(19) United States
(12) Patent Application Publication
(10) Pub. No.: US 2024/0243186 A1
(43) Pub. Date: Jul. 18, 2024

(54) SEMICONDUCTOR DEVICE STRUCTURE AND METHOD FOR FORMING THE SAME

(71) Applicant: Taiwan Semiconductor Manufacturing Company, Ltd., Hsinchu (TW)

(72) Inventors: Chun-Fu LU, Hsinchu (TW); Lung-Kun CHU, New Taipei City (TW); Jia-Ni YU, New Taipei City (TW); Mao-Lin HUANG, Hsinchu City (TW); Chung-Wei HSU, Baoshan Township (TW); Kuo-Cheng CHIANG, Zhubei City (TW); Chih-Hao WANG, Baoshan Township (TW)

(21) Appl. No.: 18/155,296

(22) Filed: Jan. 17, 2023

(51) Int. Cl. H01L 29/66; H01L 21/285; H01L 21/306; H01L 29/06; H01L 29/423; H01L 29/786

(52) U.S. Cl. CPC H01L 29/66545; H01L 21/28575; H01L 21/30604; H01L 29/0673; H01L 29/42392; H01L 29/78696

(57) ABSTRACT

A method for forming a semiconductor device structure includes forming nanostructures in a first region and a second region over a substrate. The method also includes forming a gate dielectric layer surrounding the nanostructures. The method also includes forming dummy structures between the nanostructures. The method also includes forming a dielectric layer over the nanostructures. The method also includes forming a dielectric structure between the nanostructures in the first region and nanostructures in the second region. The method also includes removing the dummy structures in the first region. The method also includes depositing a first work function layer over the nanostructures. The method also includes removing the first work function layer and the dummy structures in the second region. The method also includes depositing a second work function layer over the nanostructures.

### BACKGROUND

Semiconductor devices are used in a variety of electronic applications, such as personal computers, cell phones, digital cameras, and other electronic equipment. Semiconductor devices are typically fabricated by sequentially depositing insulating or ILD structures, conductive layers, and semiconductive layers of material over a semiconductor substrate, and patterning the various material layers using lithography to form circuit components and elements thereon. Many integrated circuits are typically manufactured on a single semiconductor wafer, and individual dies on the wafer are singulated by sawing between the integrated circuits along a scribe line. The individual dies are typically packaged separately, in multi-chip modules, for example, or in other types of packaging.

Recently, multi-gate devices have been introduced in an effort to improve gate control by increasing gate-channel coupling, reduce OFF-state current, and reduce short-channel effects (SCEs). One such multi-gate device that has been introduced is the gate-all around transistor (GAA). The GAA device gets its name from the gate structure which can extend around the channel region providing access to the channel on two or four sides. GAA devices are compatible with conventional complementary metal-oxide-semiconductor (CMOS) processes.

However, the integration of fabrication of the GAA features around the nanowire can be challenging. While the current methods have been satisfactory in many respects, continued improvements are still needed.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A-1J are perspective representations of various stages of forming a semiconductor device structure, in accordance with some embodiments of the disclosure.

FIGS. 1K-1U are cross-sectional representations of various stages of forming a semiconductor device structure, in accordance with some embodiments of the disclosure.

FIG. 1U-1 is an enlarged cross-sectional representation of a semiconductor device structure, in accordance with some embodiments of the disclosure.

FIG. 2A is a top view of a semiconductor device structure, in accordance with some embodiments of the disclosure.

FIGS. 2A-1, 2A-2, and 2B are cross-sectional representations of a semiconductor device structure, in accordance with some embodiments of the disclosure.

FIGS. 3A-3E are cross-sectional representations of various stages of forming a semiconductor device structure, in accordance with some embodiments of the disclosure.

FIG. 3E-1 is an enlarged cross-sectional representation of a semiconductor device structure, in accordance with some embodiments of the disclosure.

FIGS. 4A-4B are cross-sectional representations of various stages of forming a semiconductor device structure, in accordance with some embodiments of the disclosure.

FIGS. 5A-5B are cross-sectional representations of various stages of forming a semiconductor device structure, in accordance with some embodiments of the disclosure.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numbers are used to designate like elements. It should be understood that additional operations can be provided before, during, and after the method, and some of the operations described can be replaced or eliminated for other embodiments of the method.

The nanostructure transistor (e.g. nanosheet transistor, nanowire transistor, multi-bridge channel, nano-ribbon FET, gate all around (GAA) transistor structures) described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Embodiments for forming a semiconductor device structure are provided. The method for forming the semiconductor device structure may include forming a wall structure beside the nanostructures. The parasitic capacitance may be reduced, and the device performance may be enhanced. In addition, the process window for gate patterning may be improved. Moreover, the gate blocking structure may be formed through the wall structure and the gate structure may not be damaged. Therefore, the device density may be improved.

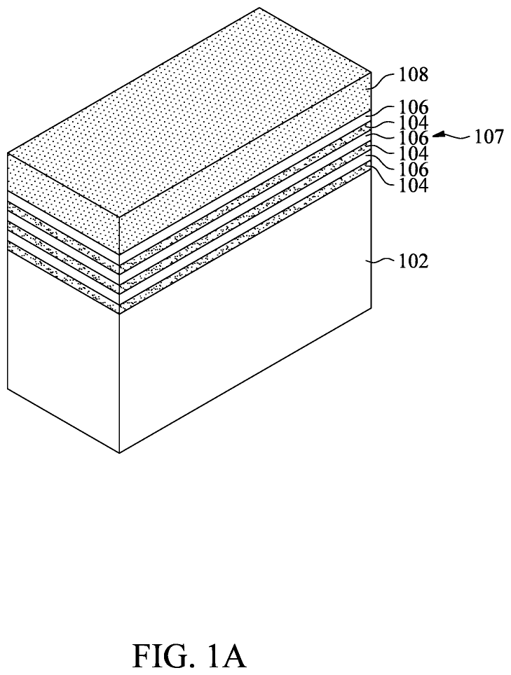

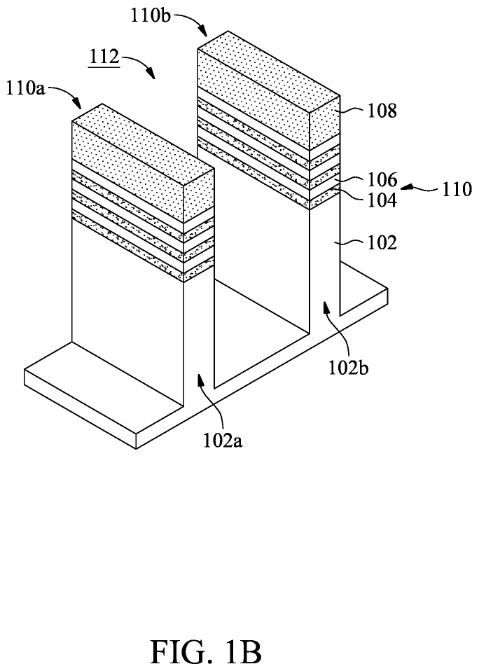

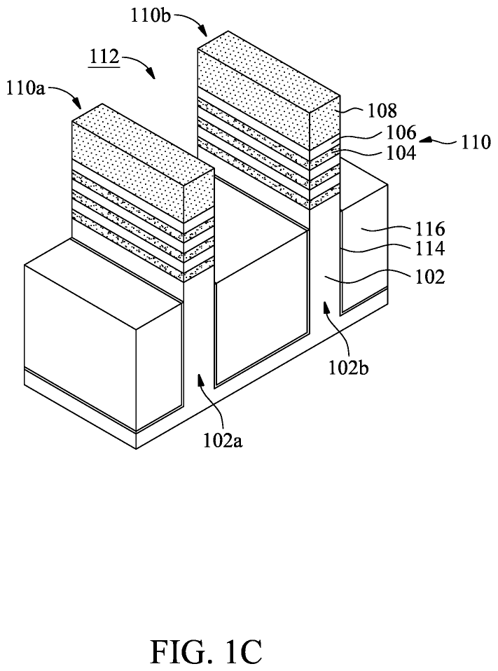

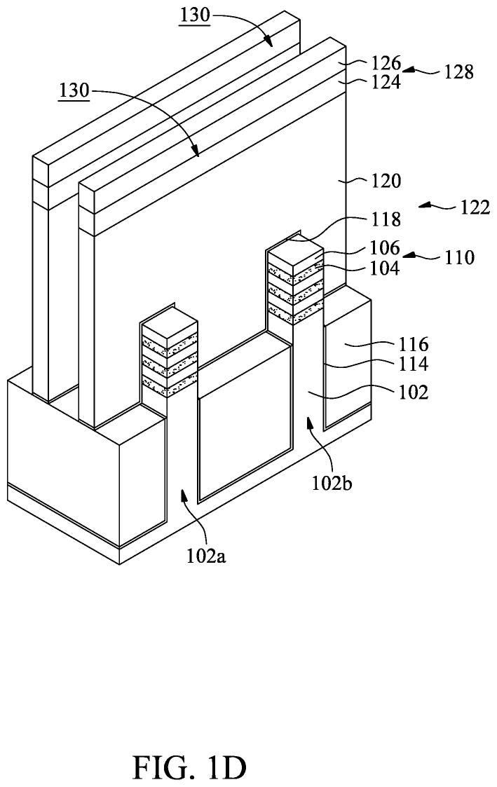

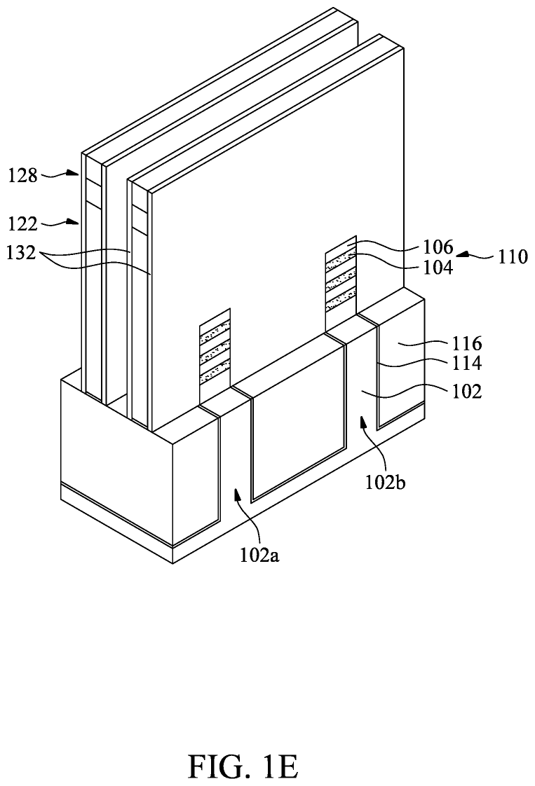

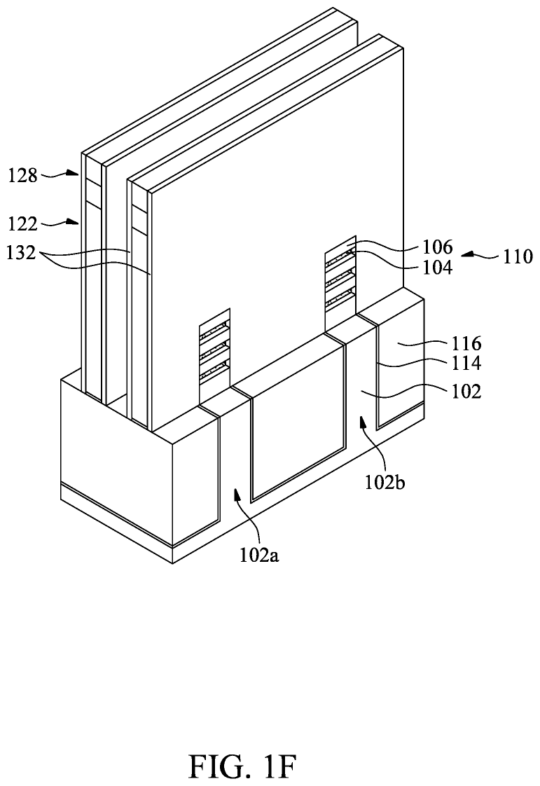

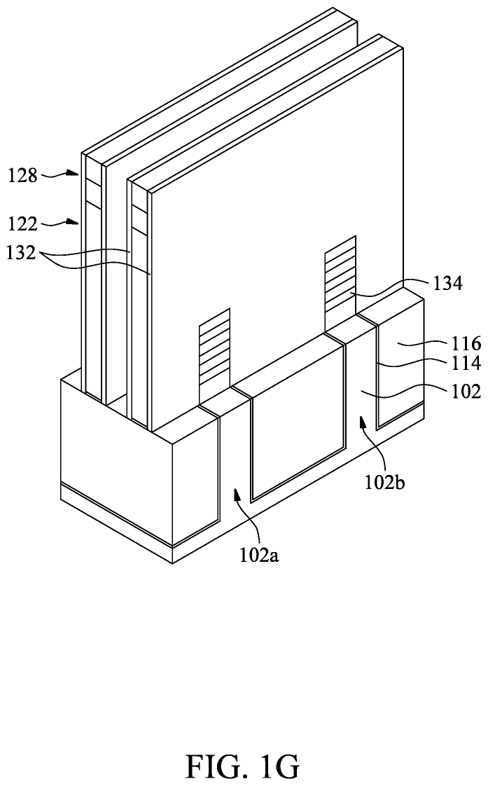

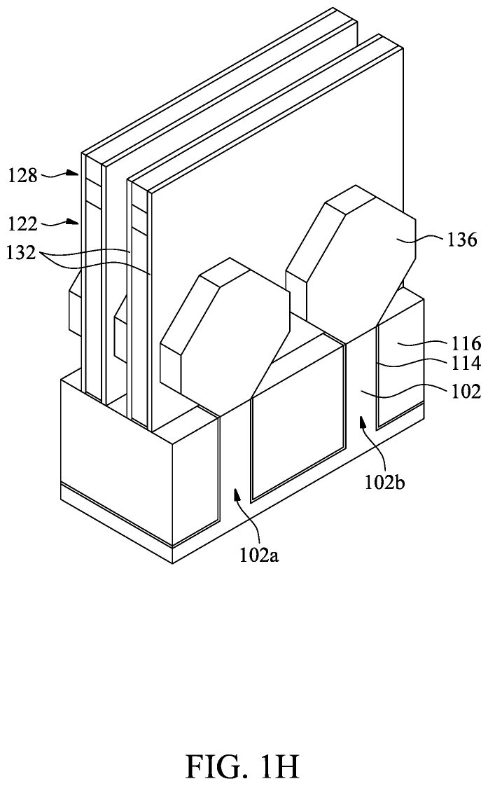

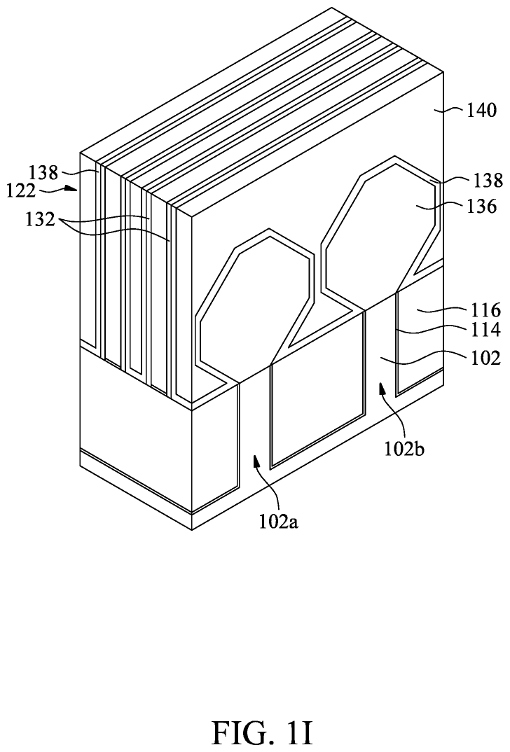

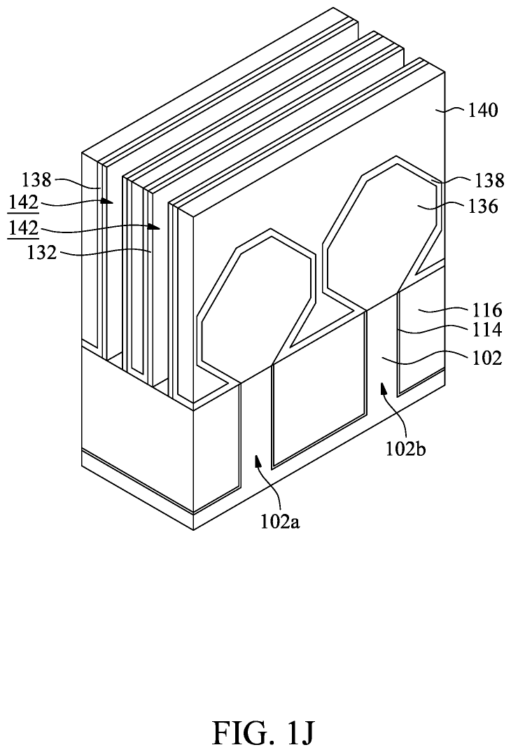

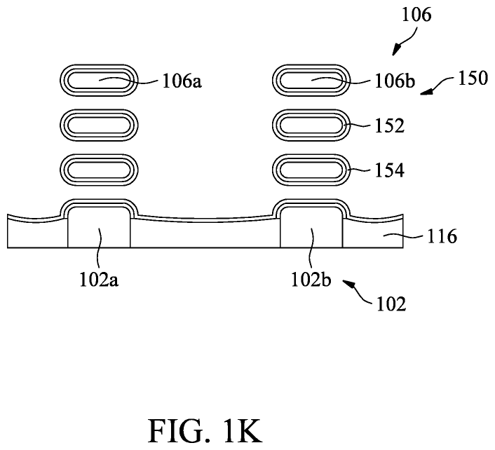

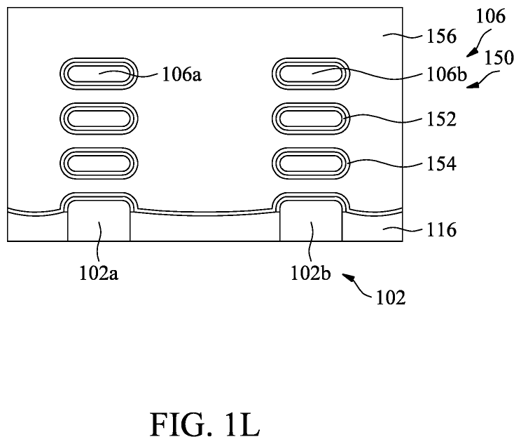

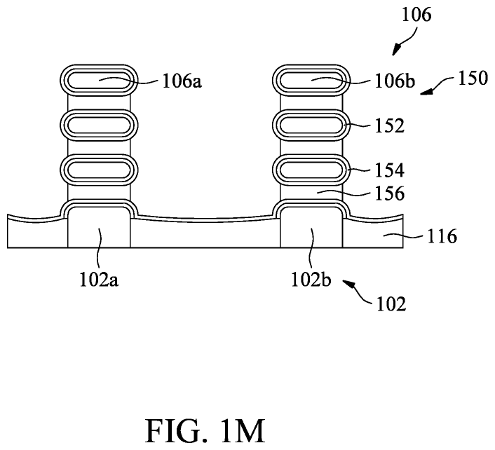

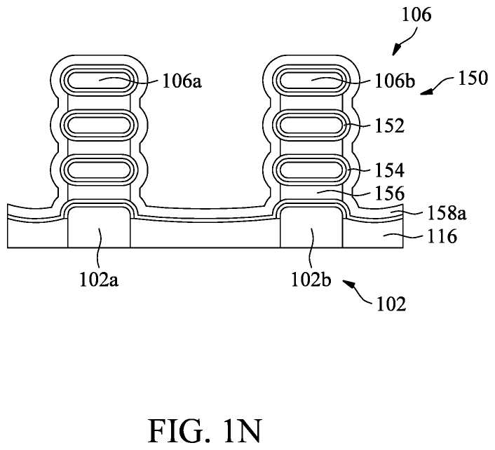

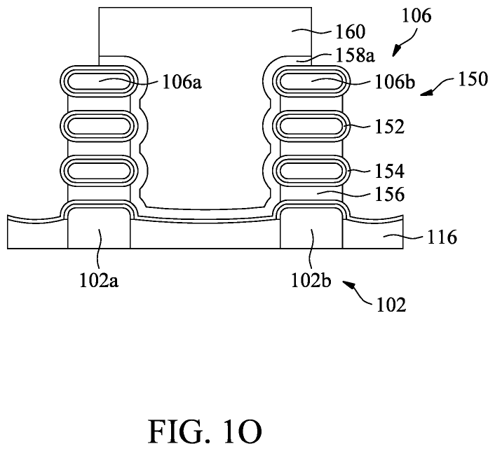

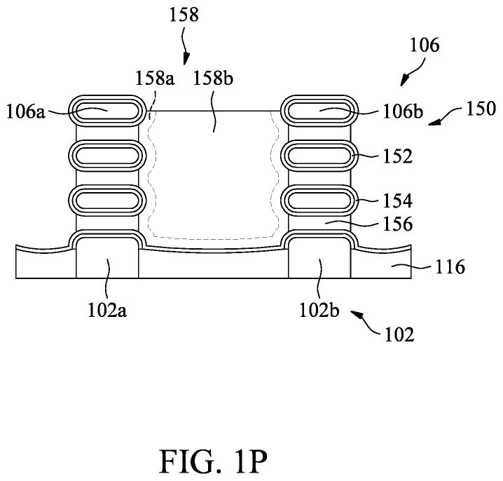

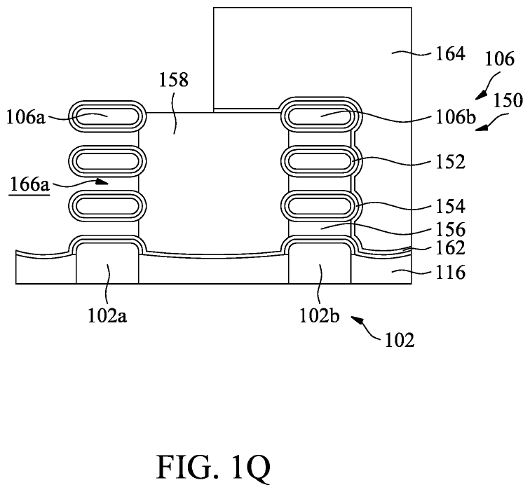

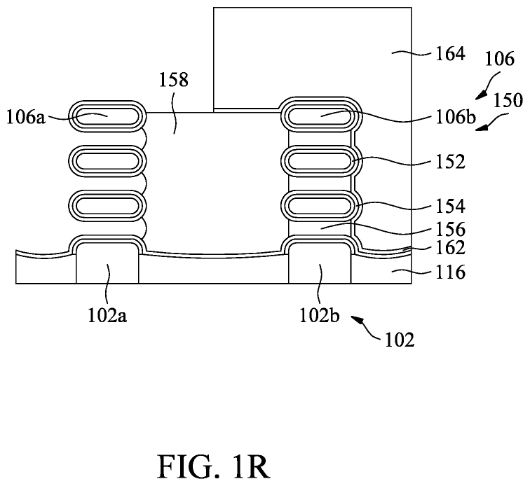

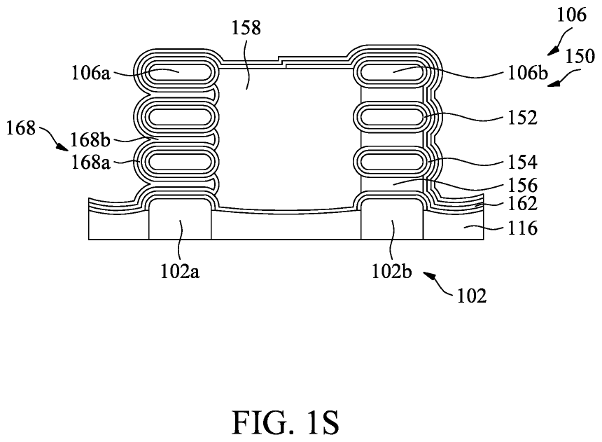

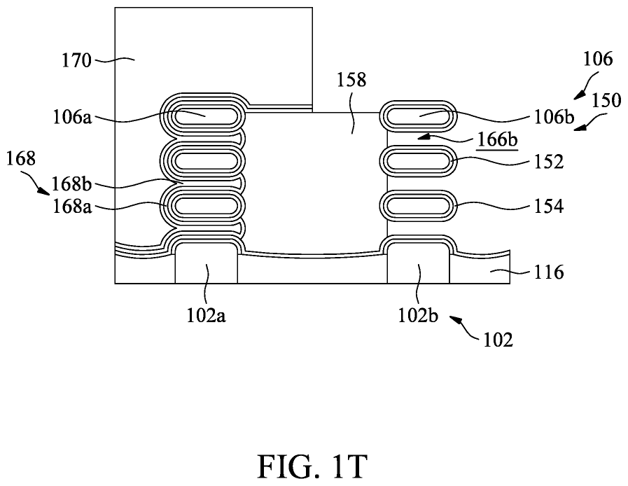

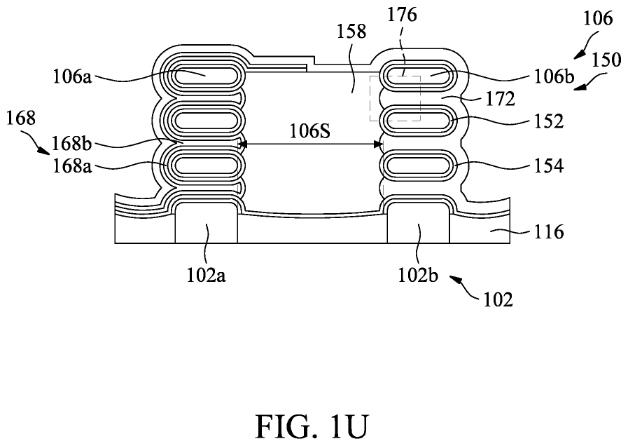

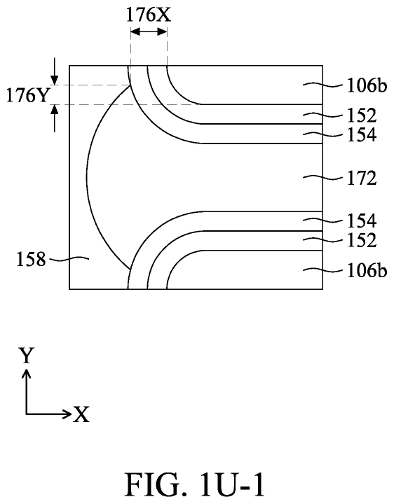

FIGS. 1A-1J are perspective representations of various stages of forming a semiconductor device structure 10a, in accordance with some embodiments of the disclosure. The semiconductor device structure 10a may be a nanostructure transistor. FIGS. 1K-1U are cross-sectional representations of various stages of forming a semiconductor device structure 10a, in accordance with some embodiments of the disclosure.

A semiconductor stack including first semiconductor material layers 104 and second semiconductor material layers 106 are formed over a substrate 102, as shown in FIG. 1A in accordance with some embodiments. The substrate 102 may be a semiconductor wafer such as a silicon wafer. The substrate 102 may also include other elementary semiconductor materials, compound semiconductor materials, and/or alloy semiconductor materials. Examples of the elementary semiconductor materials may include, but are not limited to, crystal silicon, polycrystalline silicon, amorphous silicon, germanium, and/or diamond. Examples of the compound semiconductor materials may include, but are not limited to, silicon carbide, gallium nitride, gallium arsenic, gallium phosphide, indium phosphide, indium arsenide, and/or indium antimonide. Examples of the alloy semiconductor materials may include, but are not limited to, SiGe, GaAsP, AlInAs, AlGaAs, GaInAs, GaInP, and/or GaInAsP. The substrate 102 may include an epitaxial layer. For example, the substrate 102 may be an epitaxial layer overlying a bulk semiconductor. In addition, the substrate 102 may also be semiconductor on insulator (SOI). The SOI substrate may be fabricated by a wafer bonding process, a silicon film transfer process, a separation by implantation of oxygen (SIMOX) process, other applicable methods, or a combination thereof. The substrate 102 may be an N-type substrate. The substrate 102 may be a P-type substrate.

Next, first semiconductor material layers 104 and second semiconductor material layers 106 are alternating stacked over the substrate 102 to form the semiconductor stack 107, as shown in FIG. 1A in accordance with some embodiments. The first semiconductor material layers 104 and the second semiconductor material layers 106 may include Si, Ge, SiGe, GaAs, InSb, GaP, GaSb, InAlAs, InGaAs, GaSbP, GaAsSb, or InP. The first semiconductor material layers 104 and second semiconductor material layers 106 may be made of different materials with different etching rates. In some embodiments, the first semiconductor material layers 104 are made of SiGe and the second semiconductor material layers 106 are made of Si.

The first semiconductor material layers 104 and second semiconductor material layers 106 may be formed by low pressure chemical vapor deposition (LPCVD) process, epitaxial growth process, other applicable methods, or a combination thereof. The epitaxial growth process may include molecular beam epitaxy (MBE), metal organic chemical vapor deposition (MOCVD), or vapor phase epitaxy (VPE).

It should be noted that, although there are three layers of the first semiconductor material layers 104 and three layers of the second semiconductor material layers 106 shown in FIG. 1A, the number of the first semiconductor material layers 104 and second semiconductor material layers 106 are not limited herein, depending on the demand of performance and process. For example, the semiconductor structure may include two to five layers of the first semiconductor material layers 104 and two to five layers of the second semiconductor material layers 106.

Next, a mask structure 108 is formed over the semiconductor stack 107, as shown in FIG. 1A in accordance with some embodiments. The first mask structure 108 may be made of silicon nitride, silicon carbon nitride (SiCN), or applicable material. The first hard mask layers 108 may be formed by a deposition process, such as low-pressure CVD (LPCVD) process, plasma enhanced CVD (PECVD) process, or another deposition process.

After the first semiconductor material layers 104 and the second semiconductor material layers 106 are formed as the semiconductor stack 107 over the substrate 102, the semiconductor stack 107 is patterned to form fin structures 110 using the mask structure 108 as a mask layer, as shown in FIG. 1B in accordance with some embodiments. The fin structures 110 may include base fin structures and the semiconductor stacks 107, including the first semiconductor material layers 104 and the second semiconductor material layers 106, formed over the base fin structure. The fin structures 110 may include fin structure 110a and 110b formed in the first region 102a and the second region 102b of the substrate 102, respectively.

The patterning process may including forming a mask structure 108 over the first semiconductor material layers 104 and the second semiconductor material layers 106 and etching the semiconductor stack 107 and the underlying substrate 102 through the mask structure 108, as shown in FIG. 1B in accordance with some embodiments. The mask structure 108 may be a multilayer structure including a pad layer and a hard mask layer formed over the pad layer. The pad layer may be made of silicon oxide, which may be formed by thermal oxidation or CVD. The hard mask layer may be made of silicon nitride, which may be formed by CVD, such as LPCVD or plasma-enhanced CVD (PECVD).

The patterning process of forming the fin structures 110 may include a photolithography process and an etching process. The photolithography process may include photoresist coating (e.g., spin-on coating), soft baking, mask aligning, exposure, post-exposure baking, developing the photoresist, rinsing and drying (e.g., hard baking). The etching process may include a dry etching process or a wet etching process.

After the fin structures 110 are formed, a liner layer 114 is formed over the fin structures 110 and in the trenches between the fin structures 110, as shown in FIG. 1C in accordance with some embodiments. The liner layer 114 may be conformally formed over the substrate 102, the fin structure 110, and the mask structure 108 covering the fin structure 110. The liner layer 114 may be used to protect the fin structure 110 from being damaged in the following processes (such as an anneal process or an etching process). The liner layer 114 may be made of silicon nitride. The liner layer 114 may be formed by using a thermal oxidation, a CVD process, an atomic layer deposition (ALD) process, a LPCVD process, a plasma enhanced CVD (PECVD) process, a HDPCVD process, a flowable CVD (FCVD) process, another applicable process, or a combination thereof.

Next, an isolation structure material 116 is then filled into the trenches between the fin structures 110 and over the liner layer 114, as shown in FIG. 1C in accordance with some embodiments. The isolation structure material 116 may be made of silicon oxide, silicon nitride, silicon oxynitride (SiON), fluoride-doped silicate glass (FSG), other low-k dielectric materials, or a combination thereof. The isolation structure material 116 may be deposited by a deposition process, such as a chemical vapor deposition (CVD) process (e.g. a flowable CVD (FCVD) process), a spin-on-glass process, or another applicable process.

Next, the isolation structure material 116 and the liner layer 114 are etched back using an etching process, and an isolation structure 116 is formed surrounding the base fin structure, as shown in FIG. 1C in accordance with some embodiments. The etching process may be used to remove the top portion of the liner layer 114 and the top portion of the isolation structure material 116. As a result, the first semiconductor material layers 104 and the second semiconductor material layers 106 may be exposed. The isolation structure 116 may be a shallow trench isolation (STI) structure 116. The isolation structure 116 may be configured to electrically isolate active regions such as fin structures 110 of the semiconductor structure 10a and prevent electrical interference and crosstalk.

Next, a dummy gate structure 122 is formed over and across the fin structures 110, as shown in FIG. 1D in accordance with some embodiments. The dummy gate structure 122 may be used to define the source/drain regions and the channel regions of the resulting semiconductor structure 10a. The dummy gate structure 122 may include a dummy gate dielectric layer 118 and a dummy gate electrode layer 120. The dummy gate dielectric layer 118 and the dummy gate electrode layer 120 may be replaced by the following steps to form a real gate structure with a high-k dielectric layer and a metal gate electrode layer.

The dummy gate dielectric layer 118 may include one or more dielectric materials, such as silicon oxide, silicon nitride, silicon oxynitride (SiON), HfO₂, HfZrO, HfSiO, HfTiO, HfAlO, or a combination thereof. The dummy gate dielectric layer 118 may be formed by an oxidation process (e.g., a dry oxidation process, or a wet oxidation process), a chemical vapor deposition process, other applicable processes, or a combination thereof. Alternatively, the dummy gate dielectric layer 118 may include a high-k dielectric layer (e.g., the dielectric constant is greater than 3.9) such as hafnium oxide (HfO₂). Alternatively, the high-k dielectric layer may include other high-k dielectrics, such as LaO, AlO, ZrO, TiO, Ta₂O₅, Y₂O₃, SrTiO₃, BaTiO₃, BaZrO, HfZrO, HfLaO, HfTaO, HfSiO, HfSiON, HfTiO, LaSiO, AlSiO, (Ba, Sr)TiO₃, Al₂O₃, other applicable high-k dielectric materials, or a combination thereof. The high-k dielectric layer may be formed by a chemical vapor deposition process (e.g., a plasma enhanced chemical vapor deposition (PECVD) process, or a metalorganic chemical vapor deposition (MOCVD) process), an atomic layer deposition (ALD) process (e.g., a plasma enhanced atomic layer deposition (PEALD) process), a physical vapor deposition (PVD) process (e.g., a vacuum evaporation process, or a sputtering process), other applicable processes, or a combination thereof.

The dummy gate electrode layer 120 may include polycrystalline-silicon (poly-Si), poly-crystalline silicon-germanium (poly-SiGe), other applicable materials, or a combination thereof. The dummy gate electrode layer 120 may be formed by a chemical vapor deposition process (e.g., a low pressure chemical vapor deposition process, or a plasma enhanced chemical vapor deposition process), a physical vapor deposition process (e.g., a vacuum evaporation process, or a sputtering process), other applicable processes, or a combination thereof.

Hard mask layers 128 are formed over the dummy gate structure 122, as shown in FIG. 1D in accordance with some embodiments. The hard mask layers 128 may include multiple layers, such as an oxide layer 124 and a nitride layer 126. In some embodiments, the oxide layer 124 includes silicon oxide, and the nitride layer 126 includes silicon nitride.

The formation of the dummy gate structure 122 may include conformally forming a dielectric material as the dummy gate dielectric layer 118. Afterwards, a conductive material may be formed over the dielectric material as the dummy gate electrode layers 120, and the bi-layered hard mask layers 128, including the oxide layer 124 and the nitride layer 126, may be formed over the conductive material. Next, the dielectric material and the conductive material may be patterned and etched through the bi-layered hard mask layers 128 to form the dummy gate structure 122, as shown in FIG. 1D in accordance with some embodiments. The dummy gate dielectric layer 118 and the dummy gate electrode layer 120 may be etched by a dry etching process. After the etching process, the first semiconductor material layers 104 and the second semiconductor material layers 106 may be exposed on opposite sides of the dummy gate structure 122.

Next, a conformal dielectric layer is formed over the substrate 102 and the dummy gate structure 122, and then an etching process is performed. A pair of spacer layers 132 is formed over opposite sidewalls of the dummy gate structure 122, and a source/drain opening is formed beside the dummy gate structure 122, as shown in FIG. 1E in accordance with some embodiments.

The spacer layers 132 may be multi-layer structures formed by different materials with different etching selectivity. The spacer layers 132 may be made of silicon oxide, silicon nitride, silicon oxynitride, and/or dielectric materials. The spacer layers 132 may be formed by a chemical vapor deposition (CVD) process, a spin-on-glass process, or another applicable process.

After the spacer layers 132 are formed, the first semiconductor material layers 104 and the second semiconductor material layers 106 of the fin structure 110 not covered by the dummy gate structure 122 and the spacer layers 132 are etched to form the trenches beside the dummy gate structure 122, as shown in FIG. 1E in accordance with some embodiments.

The fin structures 110 may be recessed by performing a number of etching processes. That is, the first semiconductor material layers 104 and the second semiconductor material layers 106 of the fin structures 110 may be etched in different etching processes. The etching process may be a dry etching process or a wet etching process. The fin structures 110 may be etched by a dry etching process.

Next, the first semiconductor material layers 104 are laterally etched from the source/drain opening to form recesses, as shown in FIG. 1F in accordance with some embodiments. The outer portions of the first semiconductor material layers 104 may be removed, and the inner portions of the first semiconductor material layers 104 under the dummy gate structure 122 and the spacer layers 132 may remain. After the lateral etching process, the sidewalls of the etched first semiconductor material layers 104 may be not aligned with the sidewalls of the second semiconductor material layers 106.

The lateral etching of the first semiconductor material layers 104 may be a dry etching process, a wet etching process, or a combination thereof. In some embodiments, the first semiconductor material layers 104 are Ge or SiGe and the second semiconductor material layers 106 are Si, and the first semiconductor material layers 104 are selectively etched to form the recesses by using a wet etchant such as, but not limited to, ammonium hydroxide (NH₄OH), tetramethylammonium hydroxide (TMAH), ethylenediamine pyrocatechol (EDP), or potassium hydroxide (KOH) solutions, or the like.

Next, an inner spacer 134 is formed in the recess, as shown in FIG. 1G in accordance with some embodiments. The inner spacer 134 may provide a barrier between subsequently formed source/drain epitaxial structures and gate structure. The inner spacer 134 may be made of dielectric material such as silicon oxide (SiO₂), silicon nitride (SiN), silicon carbide (SiC), silicon oxynitride (SiON), silicon carbon nitride (SiCN), silicon oxide carbonitride (SiOCN), or a combination thereof. The inner spacer 134 may be formed using a deposition process. The deposition process may include a CVD process (such as LPCVD, PECVD, SACVD, or FCVD), an ALD process, another applicable method, or a combination thereof.

Next, a source/drain epitaxial structure 136 is formed in the source/drain opening, as shown in FIG. 1H in accordance with some embodiments. The source/drain epitaxial structure 136 may be formed over opposite sides of the dummy gate structure 122. Source/drain epitaxial structure 136 may refer to a source or a drain, individually or collectively dependent upon the context.

A strained material may be grown in the source/drain opening using an epitaxial (epi) process to form the source/drain epitaxial structure 136. In addition, the lattice constant of the strained material may be different from the lattice constant of the substrate 102. The source/drain epitaxial structure 136 may include SiGeB, SiP, SiAs, SiGe, other applicable materials, or a combination thereof. The source/drain epitaxial structure 136 may be formed by an epitaxial growth step, such as metalorganic chemical vapor deposition (MOCVD), metalorganic vapor phase epitaxy (MOVPE), plasma-enhanced chemical vapor deposition (PECVD), remote plasma-enhanced chemical vapor deposition (RP-CVD), molecular beam epitaxy (MBE), hydride vapor phase epitaxy (HVPE), liquid phase epitaxy (LPE), chloride vapor phase epitaxy (Cl-VPE), or any other suitable method.

The source/drain epitaxial structure 136 may be in-situ doped during the epitaxial growth process. For example, the source/drain epitaxial structures 136 may be the epitaxially grown SiGe doped with boron (B). For example, the source/drain epitaxial structure 136 may be the epitaxially grown Si doped with carbon to form silicon:carbon (Si:C) source/drain features, phosphorous to form silicon:phosphor (Si:P) source/drain features, or both carbon and phosphorous to form silicon carbon phosphor (SiCP) source/drain features. The source/drain epitaxial structure 136 may be doped in one or more implantation processes after the epitaxial growth process.

Next, a contact etch stop layer 138 is formed over the source/drain epitaxial structure 136, as shown in FIG. 1I in accordance with some embodiments. More specifically, the contact etch stop layer 138 covers the sidewalls of the spacer layers 132 and the source/drain epitaxial structures 136 in accordance with some embodiments.

The contact etch stop layer 138 may be made of a dielectric material such as silicon nitride, silicon oxide, silicon oxynitride (SiON), other applicable materials, or a combination thereof. The contact etch stop layer 138 may be formed by a chemical vapor deposition process (e.g., a plasma enhanced chemical vapor deposition (PECVD) process, or a metalorganic chemical vapor deposition (MOCVD) process), an atomic layer deposition (ALD) process (e.g., a plasma enhanced atomic layer deposition (PEALD) process), a physical vapor deposition (PVD) process (e.g., a vacuum evaporation process, or a sputtering process), other applicable processes, or a combination thereof.

After the contact etch stop layer 138 is formed, an inter-layer dielectric (ILD) structure 140 is formed over the contact etch stop layer 138, as shown in FIG. 1I in accordance with some embodiments. The ILD structure 140 may include multilayers made of multiple dielectric materials, such as silicon oxide (SiOₓ, where x may be a positive integer), silicon oxycarbide (SiCO_{y}, where y may be a positive integer), silicon oxycarbonitride (SiNCO_{z}, where z may be a positive integer), silicon nitride, silicon oxynitride, phosphosilicate glass (PSG), borophosphosilicate glass (BPSG), low-k dielectric material, or another applicable dielectric material. Examples of low-k dielectric materials include, but are not limited to, fluorinated silica glass (FSG), carbon doped silicon oxide, amorphous fluorinated carbon, parylene, bis-benzocyclobutenes (BCB), or polyimide. The ILD structure 140 may be formed by chemical vapor deposition (CVD), physical vapor deposition (PVD), atomic layer deposition (ALD), spin-on coating, or another applicable process.

Afterwards, a planarizing process or an etch-back process is performed on the ILD structure 140 until the top surface of the dummy gate structure 122 is exposed, as shown in FIG. 1I in accordance with some embodiments. After the planarizing process, the top surface of the dummy gate structure 122 may be substantially level with the top surfaces of the spacer layers 132 and the ILD structure 140. The planarizing process may include a grinding process, a chemical mechanical polishing (CMP) process, an etching process, other applicable processes, or a combination thereof.

Next, the dummy gate structure 122 is removed, as shown in FIG. 1J in accordance with some embodiments. Therefore, a trench 142 is formed between the spacer layers 132 over the fin structure 110 and the first semiconductor material layers 104 are exposed from the trench 142.

The dummy gate structure 122 may be removed by a dry etching process or a wet etching process. The removal process may include one or more etching processes. For example, when the dummy gate electrode layers 120 are polysilicon, a wet etchant such as a tetramethylammonium hydroxide (TMAH) solution may be used to selectively remove the dummy gate electrode layers 120. Afterwards, the dummy gate dielectric layer 118 may be removed using a plasma dry etching, a dry chemical etching, and/or a wet etching.

Next, the first semiconductor material layers 104 are removed and gaps are formed between the first semiconductor material layers 104, as shown in FIG. 1K in accordance with some embodiments. More specifically, the second semiconductor material layers 106 exposed by the gaps form nanostructures 106, and the nanostructures 106 are configured to function as channel regions in the resulting semiconductor devices 10a in accordance with some embodiments. The nanostructures 106a and 106b may be formed over the first region 102a and the second region 102b of the substrate, respectively.

The first semiconductor material layers 104 may be removed by performing one or more etching processes. The etching process may include a selective wet etching process, such as APM (e.g., ammonia hydroxide-hydrogen peroxide-water mixture) etching process. The wet etching process uses etchants such as ammonium hydroxide (NH₄OH), TMAH, ethylenediamine pyrocatechol (EDP), and/or potassium hydroxide (KOH) solutions.

Next, a gate structures 150 are formed surrounding the nanostructures 106 and over the nanostructures 106, as shown in FIG. 1K in accordance with some embodiments. Gate structures 150 are formed surrounding the nanostructures 106 to form gate-all-around (GAA) transistor structures. Therefore, the gate control ability may be enhanced.

In some embodiments as shown in FIG. 1K, the gate structures 150 are multi-layered structures. Each of the gate structures 150 may include an interfacial layer 152, a gate dielectric layer 154, a work function layer, and a gate electrode layer.

The interfacial layer 152 may be formed around the nanostructures 106 and on the exposed portions of the base fin structures. The interfacial layer 152 may be made of silicon oxide, and the interfacial layer 152 may be formed by thermal oxidation. In some embodiments, the interfacial layer 152 has a thickness in a range of about 0.5 nm to about 1.5 nm.

The gate dielectric layer 154 is formed over the interfacial layer 152, so that the nanostructures 106 are surrounded (e.g. wrapped) by the gate dielectric layer 154. In addition, the gate dielectric layer 154 also covers the sidewalls of the spacer layers 132 and the inner spacers 134 in accordance with some embodiments. The gate dielectric layer 154 may be made of one or more layers of dielectric materials, such as HfO₂, HfSiO, HfSiON, HfTaO, HfTiO, HfZrO, zirconium oxide, aluminum oxide, titanium oxide, hafnium dioxide-alumina (HfO₂—Al2O₃) alloy, other applicable high-k dielectric materials, or a combination thereof. The gate dielectric layer 154 may be formed using CVD, ALD, other applicable methods, or a combination thereof. In some embodiments, the gate dielectric layer 154 has a thickness in a range of about 1.0 nm to about 2.5 nm.

After the interfacial layer 152 and the gate dielectric layer 154 are formed, a dummy material 156 is formed over and between the nanostructures 106, as shown in FIG. 1L in accordance with some embodiments. The dummy material 156 may be made of metal oxides such as AlOₓ, GaOₓ, TiOₓ, ZnO, NiOₓ, (where x may be a positive integer) or metals such as TiN, TiAl, TiAlN different to gate dielectric layer 154, the like, or a combination thereof. The dummy material 156 may be formed using CVD, ALD, other applicable methods, or a combination thereof.

Next, the dummy material 156 over the nanostructures 106 are removed, and dummy structures 156 are formed between the nanostructures 106, as shown in FIG. 1M in accordance with some embodiments. The dummy material 156 may be removed by an etching process. The etching process may include a dry etching process or a wet etching process.

By forming the dummy structures 156 between the nanostructures 106, the subsequently formed metal gate layer may not be formed between the nanostructures 106, and it may be easier to remove the dummy structures 156 than to remove the metal gate layer between the nanostructures 106 in subsequent etching processes.

Afterwards, a dielectric layer 158a is conformally formed over the nanostructures 106a and 106b and the isolation structure 116, as shown in FIG. 1N in accordance with some embodiments. The dielectric layer 158a may be made of AlOₓ, AlN, TiOₓ, ZnO, NiOₓ, SiOₓ, SiN, SiCN, SiCON, SiC (where x may be a positive integer), other applicable dielectric materials, or a combination thereof. In some embodiments, the dielectric constant of the dielectric layer 158a may be lower so that the parasitic capacitance of the semiconductor devices 10a may be lowered.

In some embodiments, the dielectric layer 158a has a thickness of about 0.5 nm to about 3.5 nm. If the dielectric layer 158a is too thick, the process boundary for the following process may be too limited. If the dielectric layer 158a is too thin, it may be difficult to define the location of the subsequently formed wall structure.

Next, a photoresist layer 160 is formed over the dielectric layer 158a, and the dielectric layer 158a is patterned by the photoresist layer 160, as shown in FIG. 1O in accordance with some embodiments. The patterning process of forming the dielectric layer 158a may include a photolithography process and an etching process. The photolithography process may include photoresist coating (e.g., spin-on coating), soft baking, mask aligning, exposure, post-exposure baking, developing the photoresist, rinsing and drying (e.g., hard baking). The etching process may include a dry etching process or a wet etching process.

After the photoresist layer 160 is removed, a dielectric structure 158b may be formed over the dielectric layer 158a. Afterwards, the dielectric structure 158b is etched back, and a wall structure 158 including the dielectric layer 158a and the dielectric structure 158b is formed between the nanostructures 106a and 106b as shown in FIG. 1P in accordance with some embodiments. In some embodiments, the dielectric structure 158b is surrounded by the dielectric layer 158a.

The dielectric structure 158b may be made of AlOₓ, AlN, TiOₓ, ZnO, NiOₓ, SiOₓ, SiN, SiCN, SiCON, SiC (where x may be a positive integer), other applicable dielectric materials, or a combination thereof. In some embodiments, the dielectric layer 158a and the dielectric structure 158b are made of the same material. Therefore, the boundary between the dielectric layer 158a and the dielectric structure 158b may be invisible, and is shown as dash line in FIG. 1P.

In some embodiments, the topmost surface of the wall structure 158 is lower than the topmost surface of the topmost nanostructures 106a and the top most surface of the topmost nanostructures 106b. In addition, the wall structure 158 is laterally spaced apart from the nanostructures 106a and the nanostructures 106b.

Afterwards, a dummy layer 162 is conformally formed over the wall structure 158 and the nanostructures 106a and 106b, as shown in FIG. 1Q in accordance with some embodiments. In some embodiments, the dummy layer 162 is formed over the dielectric structure 158b of the wall structure 158. In some embodiments, the dummy layer 162 and the dummy material 156 may be made of the same material.

Next, a photoresist layer 164 is formed over the nanostructures 106b, and the dummy layer 162 is patterned by the photoresist layer 164, and the dummy layer 162 over the nanostructures 106a is removed, as shown in FIG. 1Q in accordance with some embodiments. Moreover, the dummy structures 156 between the nanostructures 106a are removed, and gaps 166a are formed between the nanostructures 106a.

After the gaps 166a are formed, the wall structure 158 is further recessed from the gap 166a, and the gap 166a is enlarged, as shown in FIG. 1R in accordance with some embodiments. In some embodiments, the wall structure 158 is laterally recessed. The wall structure 158 may be recessed by a wet etching process. The wet etching process uses etchants such as H₃PO₄ solutions, ammonia solutions, H₂O₂ solutions, SC1, SC2, other suitable etchants, or a combination thereof. The wet etching process may be performed in a duration about 10 seconds to about 600 seconds, and process temperature between about 0° C. and about 75° C.

Next, the photoresist layer 164 is removed, and first work function layers 168 are conformally formed over the nanostructure 106a and 106b and the wall structure 158, as shown in FIG. 1S in accordance with some embodiments. The first work function layers 168 may be multi-layer structures including the first work function layers 168a and 168b. The first work function layers 168a and 168b may be conformally formed surrounding the nanostructures 106a in the first region 102a.

The first work function layers 168 may be made of a metal material. The metal material of the first work function layers 168 may include an N-work-function metal. The N-work-function metal may include tungsten (W), copper (Cu), titanium (Ti), silver (Ag), aluminum (Al), titanium aluminum alloy (TiAl), titanium aluminum nitride (TiAlN), tantalum carbide (TaC), tantalum carbon nitride (TaCN), tantalum silicon nitride (TaSiN), manganese (Mn), zirconium (Zr), or a combination thereof. The first work function layers 168 may be formed by using CVD, ALD, other applicable methods, or a combination thereof. In some embodiments, the first work function layers 168 has a thickness of about 1.0 nm to about 3.5 nm.

Next, a photoresist layer 170 is formed over the nanostructures 106a, and the first work function layers 168 are patterned by the photoresist layer 170, as shown in FIG. 1T in accordance with some embodiments. Moreover, the dummy structures 156 between the nanostructures 106b are removed, and gaps 166b are formed between the nanostructures 106b. In some embodiments, the dummy layer 162 covering the nanostructures 106b is also removed when removing the dummy structures 156 between the nanostructures 106b.

After the gaps 166b are formed, the wall structure 158 may be further recessed from the gap 166b, and the gap 166b may be enlarged. The wall structure 158 may be recessed by a wet etching process. The gap 166b may be enlarged by using the same wet etching process condition as the gap 166a is enlarged. In some embodiments, the gap 166b and the gap 166a have substantially the symmetric profile.

Next, the second work function layer 172 is conformally formed over the nanostructure 106a and 106b and the wall structure 158, as shown in FIG. 1U in accordance with some embodiments. The second work function layer 172 may be conformally formed surrounding the nanostructures 106b in the second region 102b.

The second work function layer 172 may be made of a metal material. The metal material of the second work function layer 172 may include a P-work-function metal. The P-work-function metal may include titanium nitride (TiN), tungsten nitride (WN), tantalum nitride (TaN), ruthenium (Ru) or a combination thereof. The second work function layer 172 may be formed by using CVD, ALD, other applicable methods, or a combination thereof. In some embodiments, the second work function layers 172 has a thickness of about 1.0 nm to about 3.5 nm.

In some embodiments, the wall structure 158 is surrounded by the first work function layers 168 and the second work function layer 172. In some embodiments, the wall structure 158 is in contact with the first work function layers 168 and the second work function layer 172. In some embodiments, the bottom surface of the wall structure 158 is in contact with the gate dielectric layer 154 over the isolation structure 116. In some embodiments, the bottom surface of the wall structure 158 is higher than the top surface of the isolation structure 116.

With the wall structure 158 formed between nanostructures 106a and 106b, the space 106S between the nanostructures 106a and 106b is in a range of about 20 nm to about 60 nm, as shown in FIG. 1U in accordance with some embodiments. The space 106S between the nanostructures 106a and 106b is in a range of about 35 nm to about 60 nm without the wall structure 158 formed between nanostructures 106a and 106b. The wall structure 158 may reduce the space 106S between the nanostructures 106a and 106b since the process window is improved, and the device density may be increased.

FIG. 1U-1 is an enlarged cross-sectional representation of the dashed box 176 shown in FIG. 1U. In some embodiments, the first work function layer 168 and the second work function layer 172 of the gate structures 150 protrudes toward the wall structure 158 since the gaps 166a and 166b are enlarged. The first work function layer 168 and the second work function layer 172 may protrudes toward the wall structure 158 for a distance 176X in the X-direction. In some embodiments, the distance 176X is in a range of about 0 nm to about 10 nm.

The first work function layers 168 and the second work function layers 172 may be shift from the top or bottom surface of the nanostructures 106a and 106b by a displacement 176Y in the Y-direction. In some embodiments, the displacement 176Y is in a range of about −2 nm to about 2 nm. In some embodiments, the top surface of the first work function layers 168 and the second work function layer 172 is higher than the bottom surface of the gate dielectric layer 154. In some embodiments, the top surface of the first work function layers 168 and the second work function layer 172 is higher or lower than the bottom surface of the bottom surface of the nanostructure 106b.

If the distance 176X and the displacement 176Y of the first work function layer 168 and the second work function layers 172 protrudes toward the wall structure 158 are too less, the coverage of the first work function layers 168 and the second work function layer 172 over the nanostructures 106a and 106b may be reduced, and the threshold voltage may be shifted. If the distance 176X and the displacement 176Y of the first work function layers 168 and the second work function layer 172 protrudes toward the wall structure 158 are too great, the wall structure 158 may not cover the nanostructures 106a and 106b, and the parasitic capacitance may be increased.

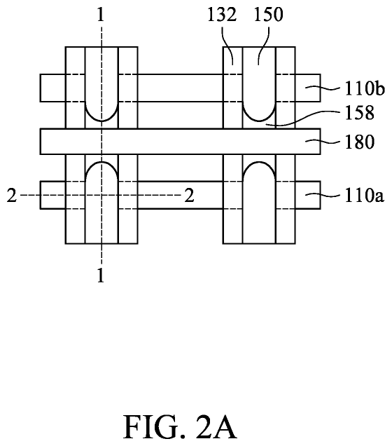

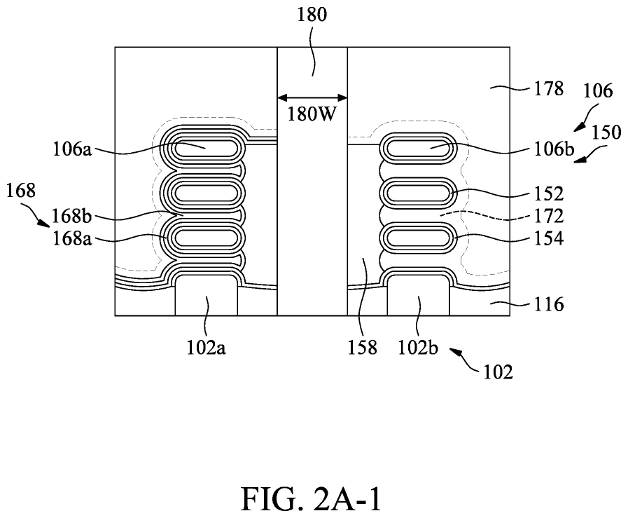

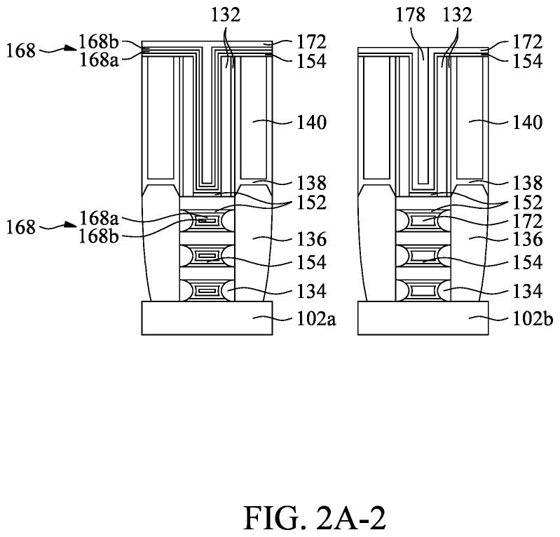

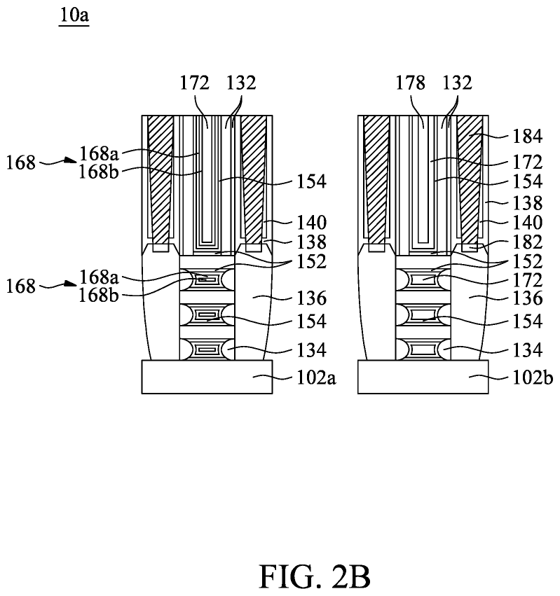

FIG. 2A is a top view of a semiconductor device structure 10a, in accordance with some embodiments of the disclosure. FIGS. 2A-1 and 2A-2 are cross-sectional representations of a semiconductor device structure 10a, in accordance with some embodiments of the disclosure. FIGS. 2A-1 and 2A-2 show cross-sectional representations taken along line 1-1 and 2-2 in FIG. 1, respectively.

Afterwards, a glue layer 178 is formed over the second work function layer 172, as shown in FIGS. 2A-1 and 2A-2 in accordance with some embodiments. The glue layer 178 may enhance the adhesion between the first work function metal layers 168 and subsequently formed layers. The glue layer 178 may be made of TiN, Ti, TaN, MoN, WN, other applicable materials, or a combination thereof. The glue layer 178 may be formed by a chemical vapor deposition process (CVD), a physical vapor deposition process (PVD), (e.g., evaporation or sputter), an atomic layer deposition process (ALD), an electroplating process, another suitable process, or a combination thereof to deposit the conductive materials of the glue layer 178. Later, a planarization process or an etch back process is performed to remove excess conductive materials. In some embodiments, the top surface of the glue layer 178 is substantially level with the top surface of the second work function layer 172 after the planarization process.

In some embodiments, the glue layer 178 and the second work function layer 172 are made of the same material. Therefore, the boundary between the glue layer 178 and the second work function layer 172 may be invisible, and is shown as dash line in FIG. 2A-1.

Next, a gate electrode layer may be formed over the glue layer 178. The gate electrode layer may be made of one or more layers of conductive material, such as aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, another suitable material, or a combination thereof. The gate electrode layer may be formed using CVD, ALD, electroplating, another applicable method, or a combination thereof. After the gate electrode layer is formed, a planarization process such as CMP or an etch-back process may be performed.

Next, a blocking structure 180 is formed between the nanostructures 106a and nanostructures 106b, as shown in FIGS. 2A and 2A-1 in accordance with some embodiments. The gate structure 150 may be cut by the blocking structure 180. In some embodiments, the blocking structure 180 directly contacts the first work function layers 168a and 168b and the glue layer 178.

A mask layer may be formed over the glue layer 178. The mask layer may be a hard mask layer made of SiN, SOC, other suitable materials, or a combination thereof. The mask layer may be formed using spin coating, LPCVD, PECVD, PVD, ALD, or other suitable processes.

Afterwards, an opening may be formed in the hard mask layer, the wall structure 158, and the isolation structure 116 between the first region 102a and the second region 102b of the substrate 102. Next, the blocking structure material may be deposited in the opening. Afterwards, a removal process, such as CMP or other suitable processes, may be performed to remove excess blocking structure material from over the glue layer 178, such that upper surfaces of the blocking structure material are substantially level with upper surfaces of the glue layer 178. Therefore, the blocking structure 180 is formed in the opening.

In some embodiments, the blocking structure 180 is formed through the dielectric structure 158b of the wall structure 158 and the isolation structure 116. In some embodiments, the wall structure 158 may formed between the ILD structures 140. The blocking structure 180 may provide isolation between the nanostructures 106a and nanostructures 106b. The blocking structure 180 may be made of SiN, SiCN, SiCON, other suitable materials, or a combination thereof. The position of the blocking structure 180 may be defined by patterning process, and the blocking structure 180 may be formed by CVD, such as LPCVD or plasma-enhanced CVD (PECVD).

In some embodiments, the blocking structure 180 has a width 180W in a range of about 10 nm to about 50 nm. In some embodiments, the blocking structure 180 is narrower than the dielectric structure 158b of the wall structure 158. Therefore, forming the blocking structure 180 may not damage the first work function layers 168 and the second work function layer 172 of the gate structure 150 and the threshold voltage may remain substantially the same.

Next, a source/drain opening is formed in the ILD structure 140, and a metal semiconductor compound layer 182 may be formed over the source/drain epitaxial structure 136, as shown in FIG. 2B in accordance with some embodiments. The metal semiconductor compound layer 182 may reduce the contact resistance between the source/drain epitaxial structure 136 and the subsequently formed source/drain contact structure over the source/drain epitaxial structure 136. The metal semiconductor compound layer 182 may be made of titanium silicide (TiSi₂), nickel silicide (NiSi), cobalt silicide (CoSi), or other suitable low-resistance materials. The metal semiconductor compound layer 182 may be formed over the source/drain epitaxial structure 136 by forming a metal layer over the source/drain epitaxial structure 136 first. The metal layer may react with the source/drain epitaxial structure 136 in an annealing process and a metal semiconductor compound layer 182 may be produced. Afterwards, the unreacted metal layer may be removed in an etching process and the metal semiconductor compound layer 182 may be left.

Next, a barrier layer (not shown) may be conformally formed over the bottom surface and the sidewalls of the source/drain opening. Afterwards, the barrier layer may be etched back. The barrier layer remains over the bottom surface of the source/drain opening. The barrier layer may be formed before filling the conductive material in the source/drain opening to prevent the conductive material from diffusing out. The barrier layer may also serve as an adhesive or glue layer. The material of the barrier layer may be TiN, Ti, other applicable materials, or a combination thereof. The barrier layer may be formed by depositing the barrier layer materials by a physical vapor deposition process (PVD) (e.g., evaporation or sputtering), an atomic layer deposition process (ALD), an electroplating process, other applicable processes, or a combination thereof.

Afterwards, a source/drain contact structure 184 is formed into the source/drain opening over the source/drain epitaxial structure 136, as shown in FIG. 2B in accordance with some embodiments. The source/drain contact structure 184 may be made of a metal material (e.g., Co, Ni, W, Ti, Ta, Cu, Al, Ru, Mo, TiN, TaN, and/or a combination thereof), metal alloys, poly-Si, other applicable conductive materials, or a combination thereof. The source/drain contact structure 184 may be formed by a chemical vapor deposition process (CVD), a physical vapor deposition process (PVD), (e.g., evaporation or sputter), an atomic layer deposition process (ALD), an electroplating process, another suitable process, or a combination thereof to deposit the conductive materials of the source/drain contact structure 184, and then a planarization process such as a chemical mechanical polishing (CMP) process or an etch back process is optionally performed to remove excess conductive materials. After the planarization process, the top surface of the source/drain contact structure 184 may be level with the top surface of the spacer layers 132.

By forming a wall structure 158 between the nanostructures 106a and nanostructures 106b, the parasitic capacitance may be lowered, and the device performance may be improved. Moreover, the metal gate patterning window may be improved and the work function layers may be less damaged, so that the device density may be further increased.

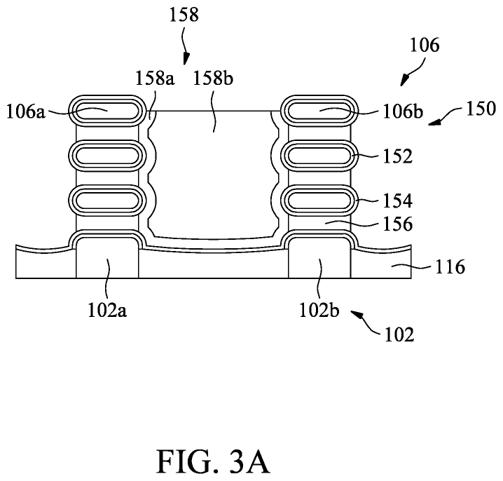

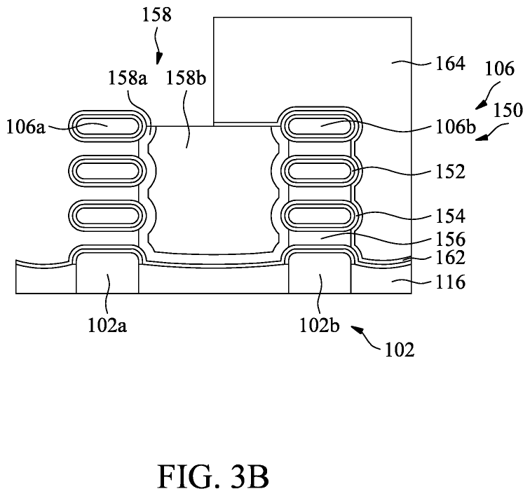

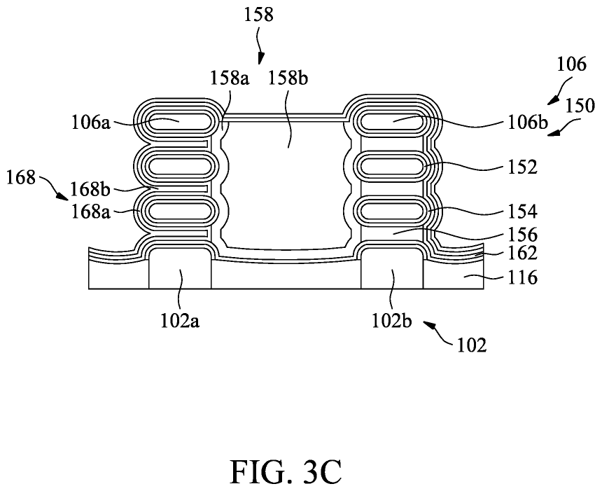

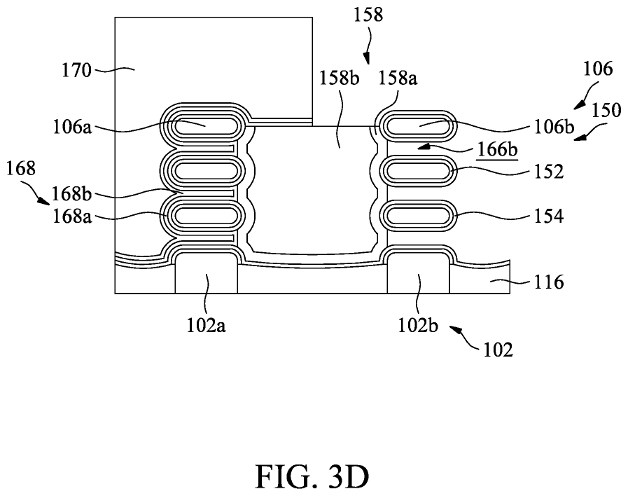

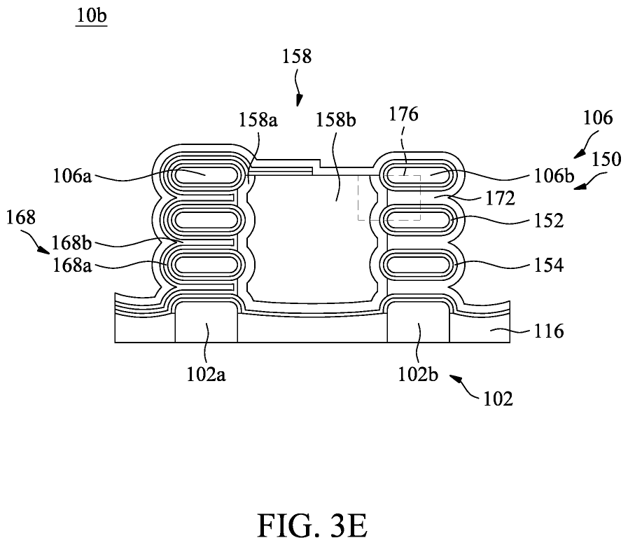

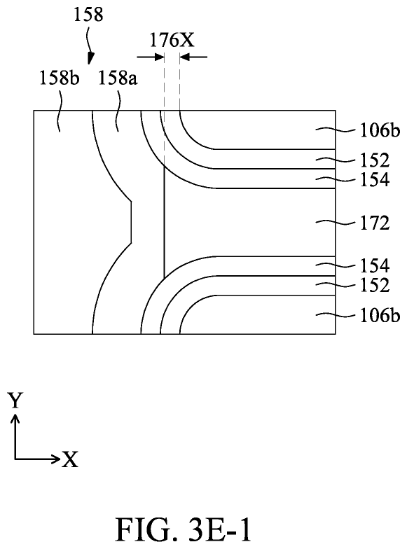

Many variations and/or modifications may be made to the embodiments of the disclosure. FIGS. 3A-3E are perspective representations of various stages of forming a semiconductor device structure 10b, in accordance with some embodiments of the disclosure. Some processes or devices are the same as, or similar to, those described in the embodiments above, and therefore the descriptions of these processes and devices are not repeated herein. The difference from the embodiments described above is that, as shown in FIG. 3A in accordance with some embodiments, the dielectric layer 158a and the dielectric structure 158b of the wall structure 158 are made of different materials.

After forming the wall structure 158, the dummy structure 156 between the nanostructures 106a are removed with the patterned photoresist layer 164, as shown in FIG. 3B in accordance with some embodiments. The first work function layers 168 are conformally formed over the nanostructure 106a and 106b and the wall structure 158, as shown in FIG. 3C in accordance with some embodiments. The first work function layers 168 covering the nanostructures 106b and the dummy structures 156 between the nanostructures 106b are removed by the patterned photoresist layer 170, as shown in FIG. 3D in accordance with some embodiments. Next, the second work function layer 172 is conformally formed over the nanostructure 106a and 106b and the wall structure 158, as shown in FIG. 3E in accordance with some embodiments.

The processes and materials for forming the first work function layers 168 and the second work function layers 172 may be the same as, or similar to, those used to form the first work function layers 168 and the second work function layers 172 in the previous embodiments. For the purpose of brevity, the descriptions of these processes and materials are not repeated herein.

In some embodiments, the dielectric layer 158a and the dielectric structure 158b are made of different materials. The material of dielectric layer 158a may have a lower dielectric constant, so that the parasitic capacitance may be reduced. The material of the dielectric structure 158b may be easier to fill in the space between the nanostructures 106a and 106b. Therefore, the void in the dielectric structure 158b may be prevented, and the yield may be improved.

FIG. 3E-1 is an enlarged cross-sectional representation of the dashed box 176 shown in FIG. 3E. In some embodiments, the sidewalls between the first work function layers 168 and the second work function layer 172 of the gate structure 150 and the wall structure 158 is substantially perpendicular to the top surface of the nanostructures 106b. The first work function layer 168 and the second work function layers 172 may be shifted from the wall structure 158 by a displacement 176X in the X-direction. In some embodiments, the displacement 176X is in a range of about −3 nm to about 3 nm.

By forming a wall structure 158 between the nanostructures 106a and nanostructures 106b, the parasitic capacitance may be lowered, and the device performance may be improved. Moreover, the metal gate patterning window may be improved and the work function layer may be less damaged, so that the device density may be further increased. The wall structure 158 may include a dielectric layer 158a and a dielectric structure 158b made of different materials. The parasitic capacitance may be lowered, and the yield may also be improved.

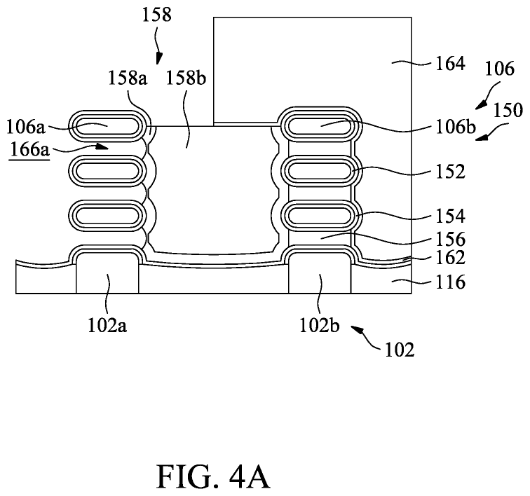

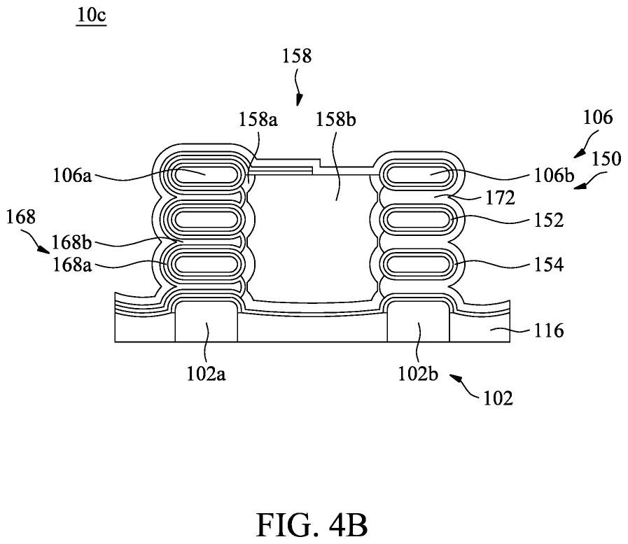

Many variations and/or modifications may be made to the embodiments of the disclosure. FIGS. 4A-4B are perspective representations of various stages of forming a semiconductor device structure 10c, in accordance with some embodiments of the disclosure. Some processes or devices are the same as, or similar to, those described in the embodiments above, and therefore the descriptions of these processes and devices are not repeated herein. The difference from the embodiments described above is that, as shown in FIG. 4A in accordance with some embodiments, the dielectric layer 158a and is recessed and the gap 166a is enlarged.

The first work function layers 168 are formed surrounding the nanostructure 106a and the second work function layer 172 is formed surrounding the nanostructure 106b, as shown in FIG. 4B in accordance with some embodiments. The processes and materials for forming the first work function layers 168 and the second work function layer 172 may be the same as, or similar to, those used to form the first work function layers 168 and the second work function layer 172 in the previous embodiments. For the purpose of brevity, the descriptions of these processes and materials are not repeated herein.

In some embodiments as shown in FIG. 4A, only the dielectric layer 158a is recessed after removing the dummy structures 156 in the first region 102a, and the first work function layers 168 and the second work function layers 172 protrudes toward the wall structure 158. Therefore, the first work function layers 168 and the second work function layer 172 cover more of the nanostructure 106a and 106b. The threshold voltage may remain substantially the same.

In some embodiments, the first work function layers 168 and the second work function layers 172 are separated from the dielectric structure 158b by the dielectric layer 158a.

By forming a wall structure 158 between the nanostructures 106a and nanostructures 106b, the parasitic capacitance may be lowered, and the device performance may be improved. Moreover, the metal gate patterning window may be improved and the work function layer may be less damaged, so that the device density may be further increased. The dielectric layer 158a may be further recessed, and the threshold voltage may remain substantially the same.

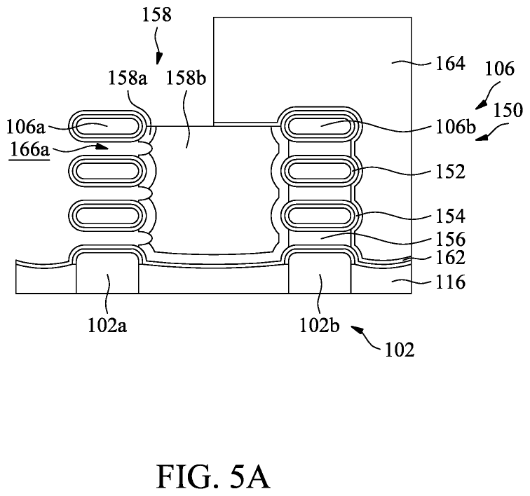

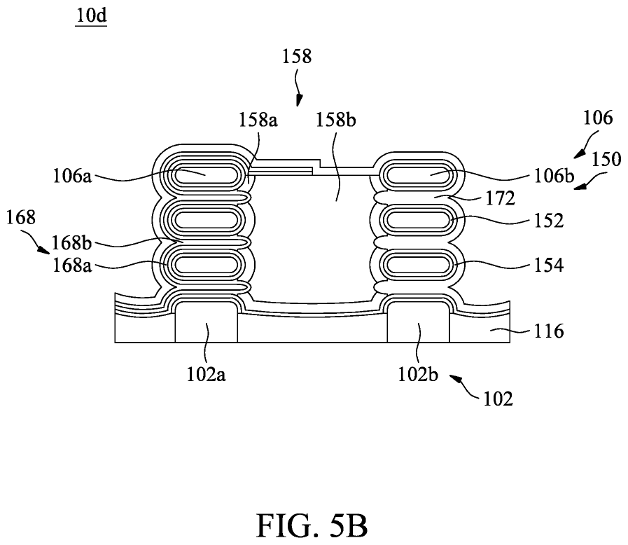

Many variations and/or modifications may be made to the embodiments of the disclosure. FIGS. 5A-5B are perspective representations of various stages of forming a semiconductor device structure 10d, in accordance with some embodiments of the disclosure. Some processes or devices are the same as, or similar to, those described in the embodiments above, and therefore the descriptions of these processes and devices are not repeated herein. The difference from the embodiments described above is that, as shown in FIG. 5A in accordance with some embodiments, the dielectric layer 158a and the dielectric structure 158b are both recessed and the gap 166a is enlarged.

The first work function layers 168 are formed surrounding the nanostructure 106a and the second work function layer 172 is formed surrounding the nanostructure 106b, as shown in FIG. 5B in accordance with some embodiments. The processes and materials for forming the first work function layers 168 and the second work function layer 172 may be the same as, or similar to, those used to form the first work function layers 168 and the second work function layer 172 in the previous embodiments. For the purpose of brevity, the descriptions of these processes and materials are not repeated herein.

In some embodiments as shown in FIG. 5A, both of the dielectric layer 158a and the dielectric structure 158b are trimmed, and the first work function layers 168 and the second work function layers 172 further protrudes toward the wall structure 158. In some embodiments, both of the dielectric layer 158a and the dielectric structure 158b are laterally recessed. Therefore, the first work function layers 168 and the second work function layers 172 cover more of the nanostructure 106a and 106b. The threshold voltage may remain substantially the same.

In some embodiments, since the dielectric layer 158a and the dielectric structure 158b are made of different materials, the dielectric layer 158a and the dielectric structure 158b are trimmed in separate etching processes, depending on the materials of the dielectric layer 158a and the dielectric structure 158b.

In some embodiments, the first work function layers 168 and the second work function layer 172 of the gate structure 150 are in direct contact with the dielectric structure 158b.

By forming a wall structure 158 between the nanostructures 106a and nanostructures 106b, the parasitic capacitance may be lowered, and the device performance may be improved. Moreover, the metal gate patterning window may be improved and the work function layer may be less damaged, so that the device density may be further increased. The dielectric layer 158a and the dielectric structure 158b of the wall structure 158 may be both further recessed, and the threshold voltage may remain substantially the same.

As described previously, a dielectric wall structure 158 is formed nanostructures 106a and 106b. With the wall structure 158, the capacitance may be lowered. The gate structure 150 may be less damaged, and there may be more process window for gate structure 150 patterning process. Therefore, the device density may be improved. In some embodiments as shown in FIG. 3A, the dielectric wall structure 158 includes dielectric layer 158a wrapping around the dielectric structure 158b with different materials. The capacitance is reduced by the dielectric layer 158a while voids in the dielectric structure 158b are prevented. In some embodiments as shown in FIG. 4B, the dielectric layer 158a is laterally recessed, and the threshold voltage remains substantially the same. In some embodiments as shown in FIG. 5B, both of the dielectric layer 158a and the dielectric structure 158b are laterally recessed, and the threshold voltage remains substantially the same.

Embodiments of a semiconductor device structure and a method for forming the same are provided. A wall structure with lower dielectric constant is formed between nanostructures. The capacitance may be reduced and the device performance may be enhanced. The patterning process window may also be improved by the wall structure. In addition, less work function layer may be damaged, and the threshold voltage remains substantially the same. Therefore, device density may be also improved.

In some embodiments, a method for forming a semiconductor device structure is provided. The method for forming a semiconductor device structure includes forming nanostructures in a first region and a second region over a substrate. The method for forming a semiconductor device structure also includes forming a gate dielectric layer surrounding the nanostructures. The method for forming a semiconductor device structure also includes forming dummy structures between the nanostructures. The method for forming a semiconductor device structure also includes forming a dielectric layer over the nanostructures. The method for forming a semiconductor device structure also includes forming a dielectric structure between the nanostructures in the first region and nanostructures in the second region. The method for forming a semiconductor device structure also includes removing the dummy structures in the first region. The method for forming a semiconductor device structure also includes depositing a first work function layer over the nanostructures. The method for forming a semiconductor device structure also includes removing the first work function layer and the dummy structures in the second region. The method for forming a semiconductor device structure also includes depositing a second work function layer over the nanostructures.

In some embodiments, a method for forming a semiconductor device structure is provided. The method for forming a semiconductor device structure includes forming first nanostructures and second nanostructures over a substrate. The method for forming a semiconductor device structure also includes forming a dummy material over and between the first nanostructures and the second nanostructures. The method for forming a semiconductor device structure also includes removing the dummy material over the first nanostructures and the second nanostructures. The method for forming a semiconductor device structure also includes depositing a dielectric layer between the first nanostructures and the second nanostructures. The method for forming a semiconductor device structure also includes forming a dielectric structure over the dielectric layer. The method for forming a semiconductor device structure also includes removing the dummy material between the first nanostructures. The method for forming a semiconductor device structure also includes forming a gate structure surrounding the first nanostructures. The method for forming a semiconductor device structure also includes removing the dummy material between the second nanostructures. The method for forming a semiconductor device structure also includes forming a second structure surrounding the second nanostructures.

In some embodiments, a semiconductor device structure is provided. The semiconductor device structure includes fin structures formed over a substrate. The semiconductor device structure also includes an isolation structure formed between the fin structures. The semiconductor device structure also includes nanostructures formed over the fin structures. The semiconductor device structure also includes gate structures surrounding the nanostructures and in a first region and a second region respectively. The semiconductor device structure also includes source/drain epitaxial structures formed over opposite sides of the gate structures. The semiconductor device structure also includes a wall structure formed between the nanostructures in the first region and the second region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device structure, comprising:
forming nanostructures in a first region and a second region over a substrate;
forming a gate dielectric layer surrounding the nanostructures;
forming dummy structures between the nanostructures;
forming a dielectric layer over the nanostructures;
forming a dielectric structure between the nanostructures in the first region and nanostructures in the second region;
removing the dummy structures in the first region;
depositing a first work function layer over the nanostructures;
removing the first work function layer and the dummy structures in the second region; and
depositing a second work function layer over the nanostructures.

2. The method for forming the semiconductor device structure as claimed in claim 1, further comprising:
recessing the dielectric layer after removing the dummy structures in the first region.

3. The method for forming the semiconductor device structure as claimed in claim 1, wherein the dielectric layer and the dielectric structure are made of different materials.

4. The method for forming the semiconductor device structure as claimed in claim 1, further comprising:
forming a blocking structure through the dielectric structure,
wherein the blocking structure is narrower than the dielectric structure.

5. The method for forming the semiconductor device structure as claimed in claim 1, further comprising:
laterally recessing the dielectric structure.

6. The method for forming the semiconductor device structure as claimed in claim 1, further comprising:
depositing a dummy layer over the nanostructures and the dummy structure.

7. The method for forming the semiconductor device structure as claimed in claim 1, wherein the first work function layer surrounds the nanostructures in the first region, and the second work function layer surrounds the nanostructures in the second region.

8. A method for forming a semiconductor device structure, comprising:
forming first nanostructures and second nanostructures over a substrate;
forming a dummy material over and between the first nanostructures and the second nanostructures;
removing the dummy material over the first nanostructures and the second nanostructures;
depositing a dielectric layer between the first nanostructures and the second nanostructures;
forming a dielectric structure over the dielectric layer;
removing the dummy material between the first nanostructures;
forming a first gate structure surrounding the first nanostructures;
removing the dummy material between the second nanostructures; and
forming a second gate structure surrounding the second nanostructures.

9. The method for forming the semiconductor device structure as claimed in claim 8,
trimming the dielectric layer and the dielectric structure.

10. The method for forming the semiconductor device structure as claimed in claim 9, wherein the dielectric layer and the dielectric structure are trimmed in separate etching processes.

11. The method for forming the semiconductor device structure as claimed in claim 8, further comprising:
forming a dummy layer over the first nanostructures, the second nanostructure, and the dielectric structure.

12. The method for forming the semiconductor device structure as claimed in claim 11, further comprising:
removing the dummy layer over the first nanostructures when removing the dummy material between the first nanostructures; and
removing the dummy layer over the second nanostructures when removing the dummy material between the second nanostructures.

13. The method for forming the semiconductor device structure as claimed in claim 11, wherein the dummy layer and the dummy material are made of the same material.

14. A semiconductor device structure, comprising:
first nanostructures and second nanostructures formed over a first region and a second region of a substrate respectively;
gate structures surrounding the first nanostructures and the second nanostructures;
source/drain epitaxial structures formed over opposite sides of the gate structures; and
a wall structure formed between the first nanostructures and the second nanostructures in the first region and the second region and laterally spaced apart from the first nanostructures and the second nanostructures,
wherein a topmost surface of the wall structure is lower than a topmost surface of the first nanostructures and a topmost surface of the second nanostructures.

15. The semiconductor device structure as claimed in claim 14, wherein the wall structure comprises:
a dielectric layer formed over the first nanostructures and the second nanostructures; and
a dielectric structure formed over the dielectric layer.

16. The semiconductor device structure as claimed in claim 15, wherein the gate structures are in contact with the dielectric structure.

17. The semiconductor device structure as claimed in claim 14, further comprising:
an isolation structure formed between the first region and the second region of the substrate,
wherein a bottom surface of the wall structure is higher than a top surface of the isolation structure.

18. The semiconductor device structure as claimed in claim 17, further comprising:
a blocking structure formed through the wall structure and the isolation structure.

19. The semiconductor device structure as claimed in claim 14, wherein the gate structures protrude towards the wall structure.

20. The semiconductor device structure as claimed in claim 14, wherein a sidewall between the gate structures and the wall structure is substantially perpendicular to top surfaces of the first nanostructures and the second nanostructures.
